(19) United States
(12) Patent Application Publication
(10) Pub. No.: US 2025/0383598 A1
(43) Pub. Date: Dec. 18, 2025

(54) MASK INSPECTION DEVICE AND METHOD FOR ADJUSTING A MASK INSPECTION DEVICE

(71) Applicant: Carl Zeiss SMT GmbH, Oberkochen (DE)

(72) Inventors: Jens Prochnau, Oberkochen (DE); Tobias Hegele, Aalen (DE)

(21) Appl. No.: 19/199,653

(22) Filed: May 6, 2025

(30) Foreign Application Priority Data
Jun. 14, 2024 (DE) 102024116721.1

(51) Int. Cl. G03F 1/84; G03F 7/00

(52) U.S. Cl. CPC G03F 1/84; G03F 7/70833; G03F 7/7085; G03F 7/70883

(57) ABSTRACT

A mask inspection device, comprising a vacuum housing, an EUV camera and, arranged in the interior of the vacuum housing, a projection lens for imaging at least one portion of an EUV photomask onto an image sensor of the EUV camera. The EUV camera is mounted on the vacuum housing. The position of the EUV camera is adjustable between a first position and a second position relative to the vacuum housing by use of an adjusting mechanism. The invention also relates to a method for adjusting a mask inspection device.

### CROSS-REFERENCE TO RELATED APPLICATION

The present application claims the priority of the German patent application DE 10 2024 116 721.1, filed on Jun. 14, 2024, the entire contents of which are incorporated herein by reference.

### TECHNICAL FIELD

The invention relates to a mask inspection device and a method for adjusting a mask inspection device.

### BACKGROUND

Photomasks are used in microlithographic projection exposure apparatuses, which are used to produce integrated circuits with particularly small structures. The photomask illuminated by very short-wave extreme ultraviolet radiation (EUV radiation) is imaged onto a lithography object in order to transfer the mask structure to the lithography object.

To ensure a high quality of the imaging created on the lithography object, it is necessary for the photomask to be true to size and not adversely affected by contaminations. It is known practice to subject photomasks to an inspection, either prior to the operation in a microlithographic projection exposure apparatus or during an interruption of operation. For this purpose, a so-called aerial image of a portion of the photomask is generated, in which case the photomask is imaged onto an EUV image sensor, rather than onto a lithography object. Using the imaging onto the EUV image sensor as a basis, it is possible to make an assessment as to whether the photomask is without defects and contaminations.

The examination is usually carried out in a mask inspection device suitable for photomasks. The mask inspection device comprises a vacuum housing, within which a projection lens defines an imaging beam path extending from the photomask as far as an image sensor of the EUV camera. It has proved to be expedient to design the mask inspection device such that the EUV camera is mounted on the vacuum housing. However, it is then not a straightforward matter to adjust the mask inspection device so as to result in entirely satisfactory imaging of the photomask onto the image sensor of the EUV camera.

### SUMMARY

The invention is based on the aspect of presenting a mask inspection device and a method for operating a mask inspection device which reduce the disadvantages mentioned. The aspect is achieved by the features of the independent claims. Advantageous embodiments are specified in the dependent claims.

A mask inspection device according to the invention comprises a vacuum housing, an EUV camera and, arranged in the interior of the vacuum housing, a projection lens for imaging a portion of an EUV photomask onto an image sensor of the EUV camera. The EUV camera is mounted on the vacuum housing. The position of the EUV camera is adjustable between a first position and a second position relative to the vacuum housing by use of an adjusting mechanism.

The invention is based on the insight that it is not a straightforward matter to adjust the imaging beam path between the photomask and the image sensor of the EUV camera by adjusting optical elements of the projection lens. A large adjusting travel would be necessary in many cases, and that is not always available in the vacuum housing of a mask inspection device. Instead, the invention proposes changing the position of the EUV camera relative to the vacuum housing in order to adjust the imaging beam path. The position of the EUV camera can be adjustable between a plurality of discrete positions. It is also possible that the position of the EUV camera can be adjusted continuously between a plurality of positions.

The mask inspection device can be designed such that changing the EUV camera between the first position and the second position comprises a displacement. Displacement denotes a movement that changes the position of the EUV camera relative to the vacuum housing, while the alignment of the EUV camera with respect to the imaging beam path remains unchanged. A displacement brings the center of gravity of the EUV camera to a different position.

Changing the EUV camera between the first position and the second position can comprise a displacement in the Z-direction. Z-direction denotes the direction of the optical axis of the last section of the beam path upstream of the EUV camera. A displacement in the Z-direction can be used to compensate for an offset of the EUV camera relative to a focal plane of the imaging beam path.

Changing the EUV camera between the first position and the second position can comprise a displacement in a direction that forms a right angle with the Z-direction. In this way, it is possible to compensate for inaccuracies resulting from the imaging beam path being displaced in a lateral direction relative to the image sensor of the EUV camera.

In addition or as an alternative thereto, a change in the position of the EUV camera between the first position and the second position can comprise a tilting of the EUV camera relative to the imaging beam path. A tilting changes the orientation of the EUV camera in space.

The tilting can be effected about an axis that forms a right angle with the Z-direction. In this way, it is possible to compensate for imaging aberrations resulting from the image sensor of the EUV camera not forming the correct angle with the Z-direction. In one embodiment, a tilting in arbitrary directions relative to the Z-direction is made possible by virtue of the fact that the EUV camera can be tilted about two mutually orthogonal axes that span a Cartesian coordinate system with the Z-direction. Other types of adjusting mechanisms that achieve the same effect are possible.

The mask inspection device can be designed such that the change in the position of the EUV camera between the first position and the second position combines a displacement with a tilting. In particular, displacement in the Z-direction can be combined with a tilting about an axis that is orthogonal to the Z-direction. In one embodiment, the mask inspection device is configured such that the position of the EUV camera is adjustable relative to the vacuum housing in all six degrees of freedom.

The adjusting mechanism used to adjust the position of the EUV camera relative to the vacuum housing can be designed for a manual actuation. In one embodiment, spacer washers arranged between the EUV camera and the vacuum housing are changed for the adjusting process. Spacer washers can be added or removed, or existing spacer washers can be replaced with others. Other adjusting mechanisms designed for a manual actuation are also possible. By way of example, it is possible to adjust one or more thread mechanisms, toothed rack mechanisms or comparable mechanisms used for mounting the EUV camera on the vacuum housing. The available adjusting travel can be for example between 0.1 mm and 2 mm, preferably between 0.2 mm and 1 mm.

It is also possible for the EUV camera to be mounted on the vacuum housing by way of one or more actuators. The actuator or the actuators can be designed, depending on a received control signal, to trigger a mechanical movement that adjusts the position of the EUV camera relative to the vacuum housing. The available adjusting travel can be for example between 0.1 mm and 2 mm, preferably between 0.2 mm and 1 mm. The mask inspection device can comprise a control unit designed to generate control signals used to control the actuators.

The control unit can be designed to process input variables in order to generate the control signals for the actuators. The input variables can be manual inputs. It is also possible to process input variables that were generated in an automatic process. The input variables can be fed to the control unit by way of data transfer.

In one embodiment, the control unit is an element of a closed control loop. In the closed control loop, the control unit can process a measured value regarding the position of the EUV camera as input variable. In one embodiment, a measured value regarding the position relative to the vacuum housing is processed. The measured value can represent the angle between the Z-direction and the plane of the image sensor of the EUV camera. In addition or as an alternative thereto, the measured value can represent the distance between an image plane of the imaging beam path and the position of the image sensor in the Z-direction. The measurement can comprise the position of the EUV camera in one or more degrees of freedom, in particular in six degrees of freedom. In one embodiment, the number of degrees of freedom of the measurement corresponds to the number of degrees of freedom of the adjusting mechanism. It is possible to process a plurality of measured values as input variables in the control unit, which concern various parameters of the position of the EUV camera relative to the vacuum housing. The control unit can be designed to determine the control commands for the actuators such that the difference between an actual position represented by the measured values and a target position is reduced. In addition or as an alternative thereto, it is also possible to process measured values representing the position of the EUV camera relative to the projection lens. The specifications applicable to the number of degrees of freedom of the measurement can be the same as those for a measurement of the position relative to the vacuum housing.

An adjusting process according to the invention can be carried out during the initial start-up of the mask inspection device in order to adjust the position of the EUV camera relative to the vacuum housing to a basic state. In addition or as an alternative thereto, an adjusting process according to the invention can be carried out during operation in order to adjust the position of the EUV camera relative to the vacuum housing between a preceding first operating phase and a succeeding second operating phase. Such an adjusting process can be carried out during a pause in operation for such an inspection direction or during ongoing operation. Both during the initial start-up and during operation, the adjusting process can be effected manually or by actuators.

In one embodiment, the mask inspection device comprises both a manually actuated adjusting mechanism and an actuator controlled by control signals in order to adjust the position of the EUV camera relative to the vacuum housing. The manually actuated adjusting mechanism can have an adjusting travel that is greater than the adjusting travel of the actuator. The adjusting travel of the manually actuated adjusting mechanism can be between 0.5 mm and 2 mm, for example. The adjusting travel of the actuator can be for example between 0.05 mm and 0.5 mm, preferably between 0.1 mm and 0.3 mm. The manually actuated adjusting mechanism can be used during the initial start-up of the mask inspection device in order to adjust the position of the EUV camera relative to the vacuum housing. The actuator can be used to adjust the position of the EUV camera relative to the vacuum housing during operation of the mask inspection device. That is based on the consideration that an adjusting travel required for adjusting the mask inspection apparatus is often larger during the initial start-up compared with a readjustment during operation. In the case of an actuator, a smaller adjusting travel makes it possible to reduce complexity and save costs.

The mask inspection device can comprise a vacuum chamber, within which the photomask is arranged during the inspection process. The vacuum chamber can be designed for a high vacuum. The pressure in the vacuum chamber during operation of the mask inspection device can be for example between 10⁻⁶ mbar and 10⁻⁹ mbar, preferably between 10⁻⁷ and 10⁻⁸ mbar. A pressure difference corresponding to the difference between the pressure in the interior of the vacuum chamber and atmospheric pressure can be present across a wall of the vacuum chamber. The wall of the vacuum chamber can be provided with a closable opening designed to make it possible to change the photomask between an interior and an exterior of the vacuum chamber.

The wall of the vacuum chamber can be partially or completely formed by the vacuum housing. In one embodiment, the EUV camera forms part of the wall of the vacuum chamber. This means that the pressure difference present across the EUV camera is the same as that present across other regions of the vacuum housing. For this purpose, the vacuum housing can have an opening that is closed in a vacuum-tight fashion when the EUV camera is mounted on the vacuum housing. In this state, the image sensor of the EUV camera can be arranged in the interior of the vacuum chamber. A housing part of the EUV camera can form a section of the wall of the vacuum chamber. The vacuum housing can have a flange which surrounds the opening and on which the EUV camera can be mounted. The pressure difference between the interior of the vacuum housing and the surroundings can be present across the EUV camera.

A flexible wall section can be formed between the EUV camera and the vacuum housing, and is subjected to a deformation when the position of the EUV camera is adjusted relative to the vacuum housing. The flexible wall section can terminate in a vacuum-tight fashion with the housing of the EUV camera and terminate in a vacuum-tight fashion with the vacuum housing. The pressure difference present across the flexible wall section can be the same as that present across other sections of the wall of the vacuum chamber. The flexible wall section can be configured for example as bellows or as a membrane. The adjusting mechanism can be arranged outside the flexible wall section, such that the adjusting mechanism is not exposed to the vacuum conditions.

If the housing of the EUV camera forms part of the wall of the vacuum chamber, considerable forces are required in order to change the position of the EUV camera relative to the vacuum housing. In order to reduce the required actuation forces, the EUV camera can be under a prestress relative to the vacuum housing, this prestress counteracting the force initiated by the vacuum. The prestress can be generated for example by spring elements arranged between the EUV camera and the vacuum housing.

Components of the EUV camera can be temperature-regulated to a temperature that deviates from the temperature in the interior of the vacuum chamber and from the ambient temperature. In particular, components of the EUV camera can be cooled to a temperature that is lower than these temperatures. For the heat transfer required for such temperature-regulation, it is advantageous if the housing of the EUV camera forms part of the vacuum chamber. Externally accessible parts of the camera housing can then be used for the heat transfer.

In an alternative embodiment, the EUV camera is arranged in the interior of the vacuum housing. Then there is not a large pressure difference present across the housing of the EUV camera. Supply lines for the EUV camera can be led through the vacuum housing. Supply lines can be intended for example for the voltage supply of the EUV camera, for the transfer of electrical signals and/or for the transfer of heat.

The supply lines can comprise a section that is exposed to the vacuum pressure in the vacuum chamber. The section can be arranged between the vacuum housing and the EUV camera. The supply lines, at least in this section, should be designed such that they withstand the vacuum conditions, which means, inter alia, that outgassings are within predefined limits. It is also possible to arrange the supply lines in this section within a vacuum-tight enclosure, such that the supply lines are not directly exposed to the vacuum conditions. The supply lines and/or the enclosures should have a sufficient flexibility. The position of the camera relative to the vacuum housing can then be adjusted without undesirable stresses occurring. The vacuum-tight enclosure can form a flexible wall section within the meaning of the invention.

In one embodiment, the mask inspection device can be designed such that the adjusting mechanism is not exposed to the vacuum conditions in the interior of the vacuum housing. In an alternative embodiment, the adjusting mechanism can comprise a first set of components arranged outside the vacuum housing. These may be, in particular, components required for the actuation or control of the adjusting mechanism. The adjusting mechanism can comprise a second set of components arranged inside the vacuum housing. These may include, in particular, components that are mechanically connected to the EUV camera. Components of the adjusting mechanism that are arranged inside the vacuum housing can be surrounded by a flexible wall section. The flexible wall section enables the first set of components to be separated from the vacuum conditions. The flexible wall section can be deformed when the position of the EUV camera is adjusted relative to the vacuum housing.

The invention does not include any limitation to a specific structural configuration of the adjusting mechanism. The adjusting mechanism can be configured for example as part of the EUV camera, as part of the vacuum housing or as a separate structural unit.

The mask inspection device can have a frame structure arranged in the vacuum housing, said frame structure carrying the optical components of the projection lens. The frame structure can be mechanically decoupled from the vacuum housing. As a result, the vacuum housing can deform, without mechanical stresses being transferred to the frame structure. A connection between the EUV camera and the frame structure can exist via the vacuum housing, on which both the frame structure and the EUV camera are mounted. In the case of such a design, it may transpire that the EUV camera changes its position relative to the frame structure as a result of the effect of disturbing influences. These may be for example thermal influences, dynamic influences, pressure differences or tolerances. The invention opens up the possibility of compensating for such changes in position by adapting the position of the EUV camera relative to the vacuum housing.

The mask inspection device can comprise an illumination system, which guides EUV radiation emerging from an EUV radiation source onto a photomask arranged in the interior of the vacuum housing. The illumination system can be configured such that the photomask is illuminated with uniform brightness. The optical components of the illumination system can be mounted on the frame structure. The projection lens, the illumination system and the frame structure can form a mechanical unit in this way. The projection lens of a mask inspection device is generally designed to generate a magnified imaging of a portion of a photomask on the EUV image sensor. The magnification factor can be greater than 20, preferably greater than 50, more preferably greater than 100.

An EUV camera according to the invention can have significantly larger dimensions than commercially available photographic cameras. The weight of the camera can be for example higher than 20 kg, preferably higher than 50 kg, more preferably higher than 100 kg. The image sensor of the camera can have the shape of an approximately rectangular array. One of the edge lengths of the rectangle spanned by the array can be between 100 mm and 200 mm, for example. An opening in the vacuum housing via which the EUV camera is mounted on the vacuum housing can have a diameter of between 500 mm and 1000 mm.

Photomasks examined in the mask inspection apparatus can have for example an aspect ratio of between 1:1 and 1:3, preferably between 1:1 and 1:2, particularly preferably of 1:1 or 1:2. The photomask can be configured in a substantially rectangular fashion. The photomask can preferably have a length and a width of 5 to 7 inches (12.7 cm to 17.8 cm), particularly preferably a length and a width of 6 inches (15.2 cm). As an alternative thereto, the photomask can have a length of 5 to 7 inches (12.7 cm to 17.8 cm) and a width of 10 to 14 inches (25.4 cm to 35.6 cm), preferably a length of 6 inches (15.2 cm) and a width of 12 inches (30.5 cm).

The invention also relates to a method for adjusting a mask inspection device, wherein the mask inspection device comprises a vacuum housing, an EUV camera and, arranged in the interior of the vacuum housing, a projection lens for imaging a portion of an EUV photomask onto an image sensor of the EUV camera. The EUV camera is mounted on the vacuum housing. The position of the EUV camera is adjusted between a first position and a second position relative to the vacuum housing by use of an adjusting mechanism, in order to adjust the EUV camera relative to the imaging beam path of the projection lens.

The disclosure encompasses developments of the method with features which are described in the context of the mask inspection device according to the invention. The disclosure encompasses developments of the mask inspection device with features which are described in the context of the method according to the invention.

### BRIEF DESCRIPTION OF DRAWINGS

The invention is described by way of example below on the basis of advantageous embodiments with reference to the accompanying drawings, in which:

FIG. 1: shows a schematic illustration of an example of a mask inspection apparatus according to the invention;

FIG. 2: shows a schematic illustration of an example of a photomask;

FIG. 3: shows a schematic sectional illustration of an example of an EUV camera;

FIG. 4: shows an aspect of an example of a mask inspection apparatus according to the invention;

FIGS. 5, 6: show alternative embodiments of adjusting mechanisms according to the invention;

FIG. 7: shows a view according to FIG. 1 in an alternative embodiment of the invention;

FIG. 8: shows an aspect of the mask inspection device from FIG. 7.

### DETAILED DESCRIPTION

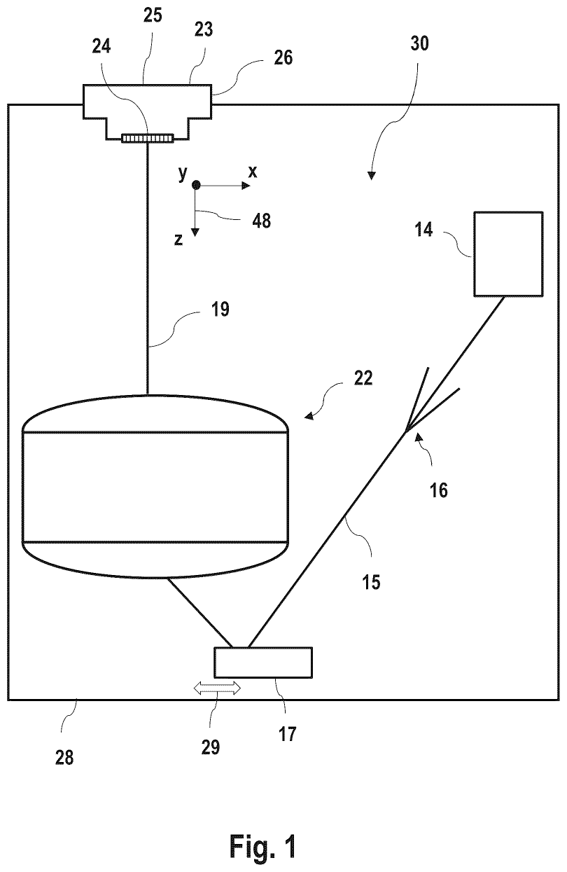

Microlithographic photomasks 17 can be examined by use of a mask inspection apparatus shown in FIG. 1.

In general, microlithographic photomasks 17 are intended to be used in a microlithographic projection exposure apparatus (not illustrated). In the microlithographic projection exposure apparatus, the photomask 17 is illuminated with extreme ultraviolet radiation (EUV radiation) at a wavelength of for example 13.5 nm in order to image a structure formed on the photomask 17 onto the surface of a lithographic object in the form of a wafer. The wafer is coated with a photoresist that reacts to the EUV radiation. The mask inspection apparatus is used to examine whether the photomask meets the requirements and is free from contamination.

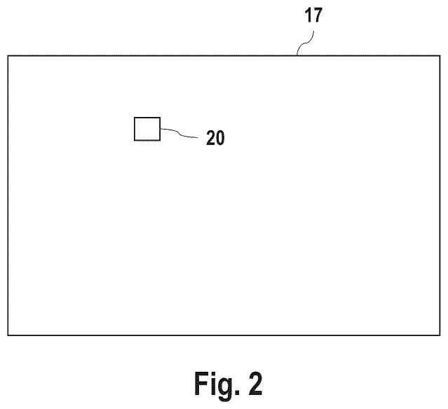

In accordance with FIG. 1, the photomask 17 is arranged in the mask inspection apparatus such that an EUV beam path 15 emanating from an EUV radiation source 14 is guided via an illumination system 16 to the photomask 17. The illumination system 16 is used to shape the EUV radiation to form a beam used to illuminate, with uniform brightness, an examination field on the surface of the photomask 17. The examination field 20, which is small in comparison with the area of the photomask 17, is depicted in FIG. 2 in an illustration that is not true to scale. For example, the illuminated region 20 may have dimensions of 0.5 mm×0.8 mm. The edge lengths of the photomask 17 can be between 100 mm and 200 mm, for example. A field stop used to delimit the illuminated region to the examination field 20 on the surface of the photomask 17 is arranged in the illumination system 16. Using a positioning mechanism 29, it is possible to move the photomask in the horizontal plane in order to bring different examination fields 20 into the region of the EUV beam path.

The EUV beam path 15 reflected at the photomask 17 continues through a projection lens 22 to an EUV camera 23, which is equipped with an image sensor 24. The image sensor may include, e.g., an array of charge-coupled device (CCD) or complementary metal-oxide-semiconductor (CMOS) sensing elements. The projection lens is used to image the examination field 20 of the photomask 17 onto the image sensor 24 of the EUV camera 23. The imaging beam path 19 is incident on the image sensor 24 in the Z-direction 48. The EUV radiation source 14, the illumination system 16, the photomask 17, the projection lens 22 and the image sensor 24 of the EUV camera 23 are arranged in a vacuum chamber 30 surrounded by a vacuum housing 28. The vacuum pump can be, e.g., a molecular pump. During operation of the mask inspection apparatus, a high vacuum is present in the vacuum chamber. The EUV camera 23 comprises a camera housing 25, which carries the image sensor 24. A rear-side part 26 of the camera housing 25 projects out of the vacuum housing 28, while the image sensor 24 is exposed to the vacuum in the vacuum housing 28. The camera housing 25 accordingly forms part of the vacuum housing 28 and is exposed to the same pressure difference as other wall regions of the vacuum chamber 30.

The EUV radiation source 14 is a plasma radiation source, in which the EUV radiation is emitted from a plasma at a wavelength of, e.g., 13.5 nm. For example, tin is a medium that can be used to generate a plasma suitable for emitting such EUV radiation. A laser beam can be made to impinge on a droplet of the medium for the purpose of generating the plasma.

In some implementations, the illumination system 16 can have one or more mirrors, and the projection lens 22 can have one or more mirrors. The mirrors in the illumination system 16 and the mirrors in the projection lens 22 are designed as EUV mirrors which have a particularly high reflectivity for EUV radiation. The optical area of the EUV mirrors can be formed by a highly reflective coating. This may be a multilayer coating, in particular a multilayer coating having alternating layers of molybdenum and silicon. Using such a coating, it is possible to reflect approximately 70% of the incident EUV radiation.

The projection lens 22 has a magnification factor of more than 100. In order to be able to record the entirety of the generated image of the examination field 20 of the photomask 17, the area of the image sensor 24 is greater than the area of the examination field 20 in accordance with the magnification factor. For example, the image sensor 24 can have dimensions of the order of magnitude of 100 mm to 200 mm.

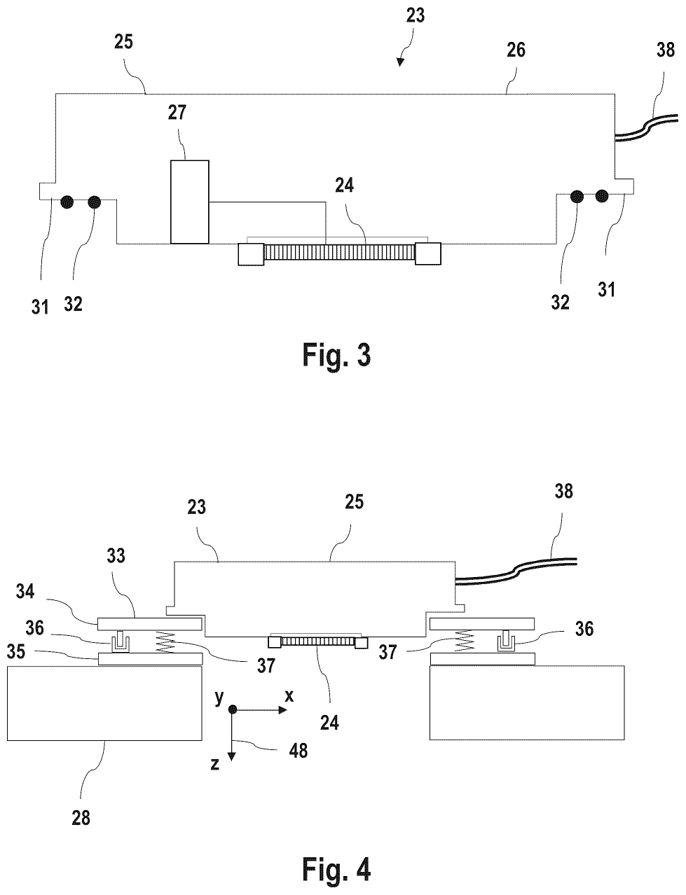

In accordance with FIG. 3, the EUV camera 23 comprises a housing 25, on which the image sensor 24 and an electronics unit 27 are arranged. By use of the electronics unit 27, the image sensor 24 is controlled, and the EUV image data obtained by the image sensor 24 are processed and output as sensor data. Via supply lines 38, the EUV camera 23 is supplied with electrical energy, the sensor data are transferred and a cooling device (not illustrated) is operated, by means of which components of the EUV camera 23 are cooled to a desired temperature.

A vacuum flange 31 is formed on the camera housing 25, and extends without interruption over the periphery of the camera housing 25. The vacuum flange 31 is equipped with two circumferential sealing rings 32 arranged one after the other in the direction of the pressure difference present across the vacuum flange 31. A connection between the EUV camera 23 and the vacuum housing 28 is established via the vacuum flange 31. In the connected state, the rear side 26 of the camera housing 25 together with the vacuum housing 28 forms a section of the wall of the vacuum chamber.

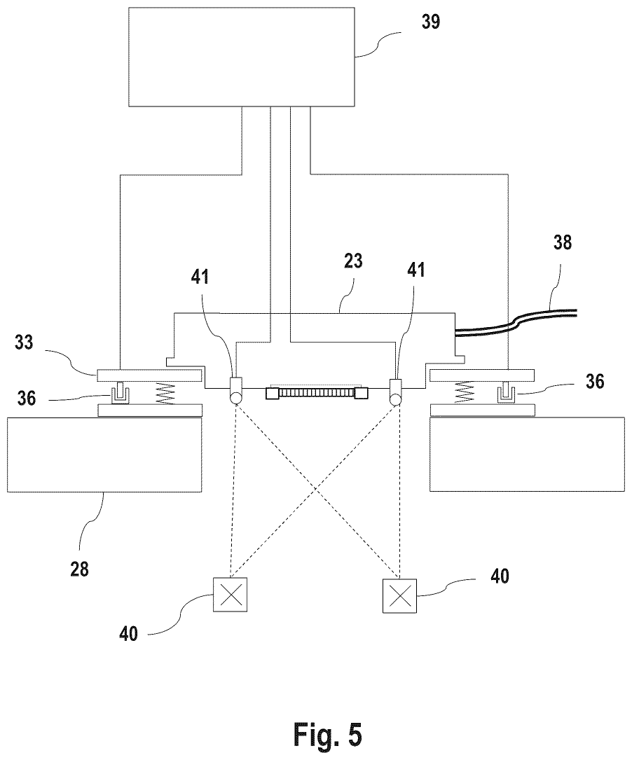

In accordance with FIG. 4, the EUV camera 23 is mounted on the vacuum housing 28 by way of an adjusting mechanism 33. The EUV camera 23 comprises an upper terminating plate 34, which is connected to the vacuum flange 31 of the EUV camera 23 in a vacuum-tight fashion. The adjusting mechanism 33 comprises a lower terminating plate 35, which is connected to the vacuum housing 28 in a vacuum-tight fashion. The interspace between the upper terminating plate 34 and the lower terminating plate 35 is sealed via a flexible wall section in the form of bellows 37. The bellows 37 extend without interruption over the periphery of the EUV camera 23. The vacuum housing 28, the camera housing 25 and the bellows 37 form sections in the wall of the vacuum chamber 30 across which the pressure difference between the high vacuum in the interior of the vacuum chamber 30 and the atmospheric pressure in the surroundings is present.

The upper terminating plate 34 and the lower terminating plate 35 are kept at a distance from one another by four actuators 36, wherein the two actuators 36 that are visible in FIG. 4 are spaced apart from one another in the X-direction, and wherein the two actuators 36 that are not visible in FIG. 4 are spaced apart from one another in the Y-direction. The actuators 36 can be adjusted in length independently of one another, as a result of which the distance between the upper terminating plate 34 and the lower terminating plate 35 of the adjusting mechanism 33 can be changed. The actuators 36 are arranged radially outside the bellows 37, such that the actuators 36 are exposed to atmospheric pressure. Each actuator can include, e.g., one or more linear motors and/or piezoelectric elements, and drive electronics that control operations of the motor(s) and/or piezoelectric elements.

By use of suitable control of the actuators 36, the position of the EUV camera 23 can be adjusted relative to the vacuum housing 28. The EUV camera 23 can be tilted about the Y-axis by means of one of the two actuators 36 that are visible in FIG. 4 being lengthened and the other being correspondingly shortened. The EUV camera 23 can be tilted about the X-axis by means of one of the two actuators 36 that are not visible in FIG. 4 being lengthened and the other being correspondingly shortened. The EUV camera 23 can be displaced in the Z-direction 48 by means of all four actuators 36 being jointly lengthened or shortened.

The actuators 36 are controlled by a control unit 39 (not shown in FIG. 4). The control unit 39 processes manual inputs from an operator in order to generate the control commands for the actuators 36. The position of the EUV camera 23 relative to the vacuum housing 28 is adjusted during the initial start-up of the mask inspection device in order to adjust the device for operation. Further adjusting processes take place in the course of maintenance work when the mask inspection device is not in operation. During ongoing operation of the mask inspection device, the actuators 36 are not actuated.

For example, the control unit 39 can include a proportional-integral-derivative (PID) control unit, and/or a digital signal processing (DSP) unit. In some examples, the control unit 39 can include one or more data processors. Each data processor can include one or more processor cores, and each processor core can include logic circuitry for processing data. For example, a data processor can include an arithmetic and logic unit (ALU), a control module, and various registers. Each data processor can include cache memory. Each data processor can include a system-on-chip (SoC) that includes multiple processor cores, random access memory, graphics processing units, one or more control modules, and one or more communication modules. Each data processor can include many transistors.

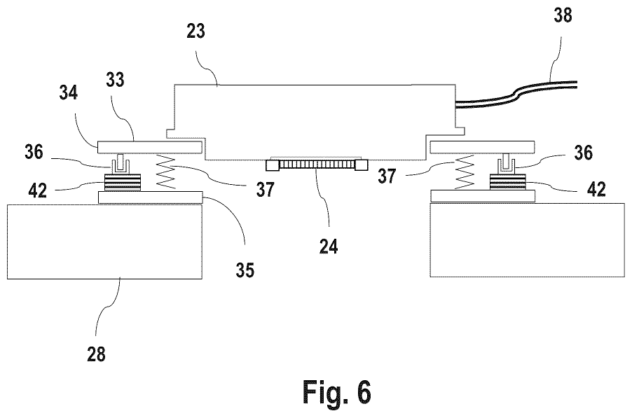

FIG. 5 illustrates an alternative embodiment, in which the EUV camera 23 is equipped with a plurality of distance sensors 41. The distance sensors 41 are designed to measure the distance to targets 40 mounted on the projection lens 22. The measured values from the distance sensors 41 are processed in the control unit 39 in order to determine whether the EUV camera 23 has the correct position relative to the projection lens 22. If this is not the case, the control unit 39 transmits control commands to the actuators 36, such that the difference between the actual position determined by the distance sensors 41 and a target position of the EUV camera 23 is reduced. The distance sensors 41, the control unit 39 and the actuators 36 are elements of a closed control loop. The control loop is active during operation of the mask inspection apparatus, such that the position of the EUV camera 23 is constantly adapted to the current conditions.

In the case of the embodiment in accordance with FIG. 6, the adjusting mechanism 33 comprises a plurality of spacer washers 42 between each of the actuators 36 and the lower terminating plate 35 of the adjusting mechanism 33. In the course of the initial start-up of the mask inspection device, the number of spacer washers 42 is chosen individually for each of the actuators 36 so as to result in a basic setting in which the EUV camera 23 has approximately the appropriate alignment relative to the projection lens 22. The further fine setting takes place during operation by way of the actuators 36.

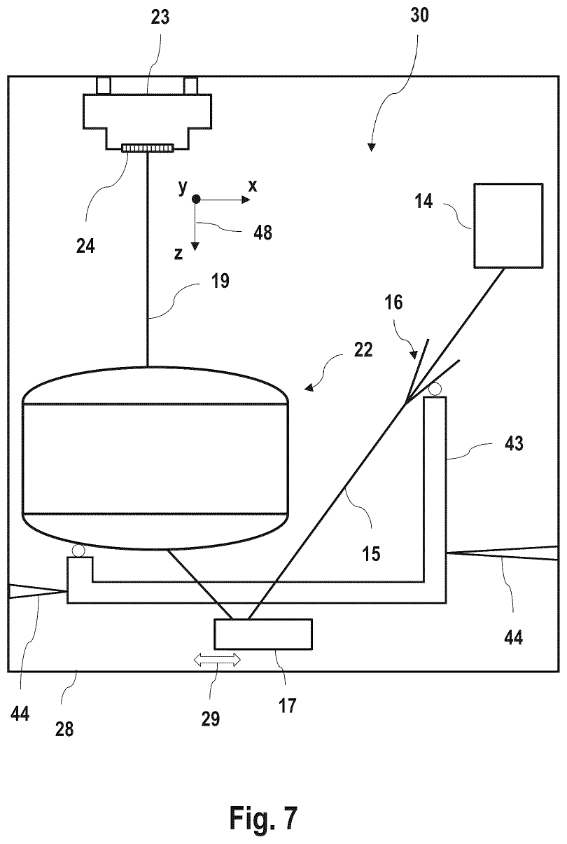

FIG. 7 shows a further embodiment, in which the EUV camera 23 is arranged in the vacuum chamber 30 and is suspended from the inner side of the vacuum housing 28. The mask inspection device comprises a frame structure 43 carrying the illumination system 16 and the projection lens 22. The frame structure 43 is mounted on the vacuum housing 28 via a suspension 44, wherein the suspension 44 is designed such that the frame structure 43 is mechanically decoupled from the vacuum housing 28. The vacuum housing 28 can thus experience a thermal expansion, for example, without this being transferred to the frame structure 43 via the suspension 44. The photomask 17 is connected to the vacuum housing 28 rather than to the frame structure 43. Changes in the position of the EUV camera 23 that result from relative movements between the vacuum housing 28 and the frame structure 43 can be compensated for according to the invention by the position of the EUV camera 23 being changed relative to the vacuum housing 28.

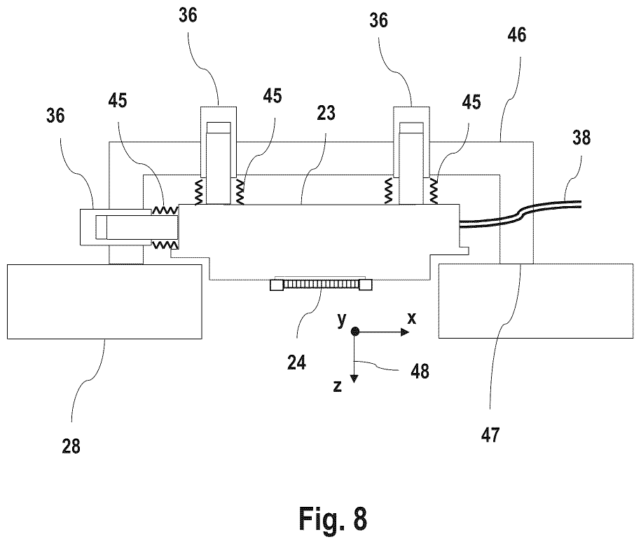

In accordance with FIG. 8, the vacuum housing 28 comprises a housing cover 46, which is connected to the vacuum housing 28 in a vacuum-tight fashion via a flange 47. The vacuum cover 46 carries the EUV camera 23 by way of a plurality of actuators 36. The actuators 36 can be designed for a lower actuation force (as compared to the actuators 36 of FIGS. 4 to 6) because the pressure difference between the vacuum conditions and atmospheric pressure is not present across the EUV camera 23.

The actuators 36 extend through the housing cover 46 and can be controlled with control signals via an outer section. An inner section of the actuators 36 bridges the distance between the inner side of the housing cover 46 and the EUV camera 23. The inner section of an actuator 36 is surrounded by a flexible wall in the form of a tubular membrane 45, with the result that the inner section of the actuator 36 is not exposed to the vacuum conditions in the interior of the vacuum housing 28 either. The supply lines 38 extend through the interspace between the housing cover 46 and the EUV camera 23 and are designed such that they withstand the vacuum conditions.

The adjusting mechanism comprises a plurality of actuators 36, by means of which the EUV camera, as described, can be displaced in the Z-direction 48 and can be tilted about the X-axis and the Y-axis. The adjusting mechanism comprises a further actuator 36, the adjusting travel of which is oriented horizontally, such that the EUV camera 23 can be displaced within the X-Y plane relative to the housing cover 46.

In some implementations, the actuators 36 can have an adjusting travel of between 0.1 mm and 2 mm, preferably between 0.2 mm and 1 mm.

Furthermore, while some embodiments, examples or aspects described herein include some but not other features included in other embodiments, examples or aspects combinations of features of different embodiments, examples or aspects are meant to be within the scope of the claims, and form different embodiments, as would be understood by those skilled in the art.

The following are examples of a mask inspection device and an example of a method for adjusting a mask inspection device. The reference numbers included in these examples are merely for illustrative purposes and do not limit the scope of the claims.

Embodiment 1. Mask inspection device, comprising a vacuum housing (28), an EUV camera (23) and, arranged in the interior of the vacuum housing (28), a projection lens (22) for imaging at least one portion (20) of an EUV photomask (17) onto an image sensor (24) of the EUV camera (23), wherein the EUV camera (23) is mounted on the vacuum housing (28) and wherein the position of the EUV camera (23) is adjustable between a first position and a second position relative to the vacuum housing (28) by use of an adjusting mechanism (33).

Embodiment 2. Mask inspection device according to Embodiment 1, wherein the transition of the EUV camera (23) between the first position and the second position comprises a displacement of the EUV camera (23) in the Z-direction (48).

Embodiment 3. Mask inspection device according to Embodiment 1 or 2, wherein the transition of the EUV camera (23) between the first position and the second position comprises a tilting of the EUV camera (23) about an axis orthogonal to the Z-direction (48).

Embodiment 4. Mask inspection device according to any of Embodiments 1 to 3, wherein the transition of the EUV camera (23) between the first position and the second position combines a displacement of the EUV camera (23) with a tilting of the EUV camera (23).

Embodiment 5. Mask inspection device according to any of Embodiments 1 to 4, wherein the EUV camera (23) is adjustable between a plurality of positions relative to the vacuum housing (28).

Embodiment 6. Mask inspection device according to any of Embodiments 1 to 5, wherein the adjusting mechanism (33) on the vacuum housing (28) is designed for a manual actuation.

Embodiment 7. Mask inspection device according to any of Embodiments 1 to 6, wherein the adjusting mechanism (33) is designed for an actuation by use of actuators (36).

Embodiment 8. Mask inspection device according to any of Embodiments 1 to 7, wherein the adjusting mechanism (33) has an adjusting travel of between 0.1 mm and 2 mm.

Embodiment 9. Mask inspection device according to Embodiment 7 or 8, comprising a control unit (39) designed to process input variables in order to generate control signals for the actuators (36).

Embodiment 10. Mask inspection device according to Embodiment 9, wherein the control unit (39) is an element of a closed control loop and wherein the control unit processes a measured value regarding the position of the EUV camera (23) as input variable.

Embodiment 11. Mask inspection device according to Embodiment 10, wherein the measured value represents the position of the EUV camera (23) relative to the projection lens (22).

Embodiment 12. Mask inspection device according to Embodiment 10 or 11, wherein the measured value represents the position of the EUV camera (23) relative to the vacuum housing (28).

Embodiment 13. Mask inspection device according to any of Embodiments 1 to 12, wherein the vacuum housing (28) comprises an opening that is closed in a vacuum-tight fashion when the EUV camera (23) is mounted on the vacuum housing (28).

Embodiment 14. Mask inspection device according to Embodiment 13, wherein the pressure difference between the interior of the vacuum housing (28) and the surroundings is present across the EUV camera (23).

Embodiment 15. Mask inspection device according to any of Embodiments 1 to 13, wherein the EUV camera (23) is arranged in the interior of the vacuum housing (28).

Embodiment 16. Mask inspection device according to any of Embodiments 1 to 15, wherein a flexible wall section (37, 45) is formed between the EUV camera (23) and the vacuum housing (28), and is subjected to a deformation when the position of the EUV camera (23) is adjusted relative to the vacuum housing (28).

Embodiment 17. Mask inspection device according to any of Embodiments 1 to 16, wherein the adjusting mechanism (33) is not exposed to the vacuum conditions in the interior of the vacuum housing (28).

Embodiment 18. Mask inspection device according to any of Embodiments 1 to 17, comprising a frame structure (43) carrying the optical components of the projection lens (22), wherein the frame structure (43) is mechanically decoupled from the vacuum housing (28).

Embodiment 19. Method for adjusting a mask inspection device, wherein the mask inspection device comprises a vacuum housing (28), an EUV camera (23) and, arranged in the interior of the vacuum housing (28), a projection lens (22) for imaging a portion (20) of an EUV photomask (17) onto an image sensor (24) of the EUV camera (23), wherein the EUV camera (23) is mounted on the vacuum housing (28) and wherein the position of the EUV camera (23) is adjusted between a first position and a second position relative to the vacuum housing (28) by use of an adjusting mechanism (33), in order to adjust the EUV camera (23) relative to the imaging beam path of the projection lens (22).

What is claimed is:

1. A mask inspection device, comprising a vacuum housing, an EUV camera and, arranged in the interior of the vacuum housing, a projection lens for imaging at least one portion of an EUV photomask onto an image sensor of the EUV camera, wherein the EUV camera is mounted on the vacuum housing and wherein the position of the EUV camera is adjustable between a first position and a second position relative to the vacuum housing by use of an adjusting mechanism.

2. The mask inspection device of claim 1, wherein the transition of the EUV camera between the first position and the second position comprises a displacement of the EUV camera in the Z-direction.

3. The mask inspection device of claim 1, wherein the transition of the EUV camera between the first position and the second position comprises a tilting of the EUV camera about an axis orthogonal to the Z-direction.

4. The mask inspection device of claim 1, wherein the transition of the EUV camera between the first position and the second position combines a displacement of the EUV camera with a tilting of the EUV camera.

5. The mask inspection device of claim 1, wherein the EUV camera is adjustable between a plurality of positions relative to the vacuum housing.

6. The mask inspection device of claim 1, wherein the adjusting mechanism on the vacuum housing is designed for a manual actuation.

7. The mask inspection device of claim 1, wherein the adjusting mechanism is designed for an actuation by use of actuators.

8. The mask inspection device of claim 1, wherein the adjusting mechanism has an adjusting travel of between 0.1 mm and 2 mm.

9. The mask inspection device of claim 7, comprising a control unit designed to process input variables in order to generate control signals for the actuators.

10. The mask inspection device of claim 9, wherein the control unit is an element of a closed control loop and wherein the control unit processes a measured value regarding the position of the EUV camera as input variable.

11. The mask inspection device of claim 10, wherein the measured value represents the position of the EUV camera relative to the projection lens.

12. The mask inspection device of claim 10, wherein the measured value represents the position of the EUV camera relative to the vacuum housing.

13. The mask inspection device of claim 1, wherein the vacuum housing comprises an opening that is closed in a vacuum-tight fashion when the EUV camera is mounted on the vacuum housing.

14. The mask inspection device of claim 13, wherein the pressure difference between the interior of the vacuum housing and the surroundings is present across the EUV camera.

15. The mask inspection device of claim 1, wherein the EUV camera is arranged in the interior of the vacuum housing.

16. The mask inspection device of claim 1, wherein a flexible wall section is formed between the EUV camera and the vacuum housing, and is subjected to a deformation when the position of the EUV camera is adjusted relative to the vacuum housing.

17. The mask inspection device of claim 1, wherein the adjusting mechanism is not exposed to the vacuum conditions in the interior of the vacuum housing.

18. The mask inspection device of claim 1, comprising a frame structure carrying the optical components of the projection lens, wherein the frame structure is mechanically decoupled from the vacuum housing.

19. A method for adjusting a mask inspection device, wherein the mask inspection device comprises a vacuum housing, an EUV camera and, arranged in the interior of the vacuum housing, a projection lens for imaging a portion of an EUV photomask onto an image sensor of the EUV camera, wherein the EUV camera is mounted on the vacuum housing and wherein the position of the EUV camera is adjusted between a first position and a second position relative to the vacuum housing by use of an adjusting mechanism, in order to adjust the EUV camera relative to the imaging beam path of the projection lens.

20. The method of claim 19, wherein adjusting the EUV camera between the first position and the second position comprises displacing the EUV camera in the Z-direction.
